(19) United States
(12) Patent Application Publication
(10) Pub. No.: US 2023/0299103 A1
(43) Pub. Date: Sep. 21, 2023

(54) LIGHT DETECTOR, LIGHT DETECTION SYSTEM, LIDAR DEVICE, AND MOBILE BODY

(71) Applicant: KABUSHIKI KAISHA TOSHIBA, Tokyo (JP)

(72) Inventors: Ryomo KANEKO, Ota Tokyo (JP); Mariko SHIMIZU, Setagaya Tokyo (JP); Keita SASAKI, Yokohama Kanagawa (JP); Honam KWON, Kawasaki Kanagawa (JP); Ikuo FUJIWARA, Yokohama Kanagawa (JP); Kazuhiro SUZUKI, Meguro Tokyo (JP)

(73) Assignee: KABUSHIKI KAISHA TOSHIBA, Tokyo (JP)

(21) Appl. No.: 17/822,417

(22) Filed: Aug. 25, 2022

(30) Foreign Application Priority Data
Mar. 15, 2022 (JP) 2022-040382

(51) Int. Cl. H01L 27/146; G01S 17/89

(52) U.S. Cl. CPC H01L 27/14623; H01L 27/1463; G01S 17/89; H01L 27/14649; H01L 27/14627

(57) ABSTRACT

A light detector according to one embodiment, includes an element region, a light concentrator, a structure part and a light-shielding part. The element region includes a first semiconductor region of a first conductivity type, and a second semiconductor region of a second conductivity type. The light concentrator is separated from the element region in a first direction. The light concentrator is configured to concentrate light incident on the light concentrator. The structure part is arranged with the element region in a direction crossing the first direction. The structure part has a different refractive index from the element region. The light-shielding part is located between the element region and the light concentrator. The light-shielding part includes an opening. At least a portion of the light incident on the light concentrator is able to be incident on the element region by passing through the opening.

### CROSS-REFERENCE TO RELATED APPLICATIONS

This application is based upon and claims the benefit of priority from Japanese Patent Application No. 2022-040382, filed on Mar. 15, 2022; the entire contents of which are incorporated herein by reference.

### FIELD

Embodiments relate to a light detector, a light detection system, a lidar device, and a mobile body.

### BACKGROUND

There is a light detector that detects light incident on a semiconductor region. It is desirable to increase the detection efficiency of the light detector.

### BRIEF DESCRIPTION OF THE DRAWINGS

FIG. 1 is a schematic cross-sectional view illustrating a light detector according to an embodiment;

FIG. 2 is a schematic plan view illustrating a portion of the light detector according to the embodiment;

FIG. 3 is a graph illustrating characteristics of light detectors;

FIGS. 4A to 4D are schematic plan views illustrating light-shielding parts of the light detector according to the embodiment;

FIGS. 5A and 5B are schematic cross-sectional views illustrating a portion of the light detector according to the embodiment;

FIG. 6 is a schematic plan view illustrating another light detector according to the embodiment;

FIG. 7 is a schematic plan view illustrating a portion of another light detector according to the embodiment;

FIG. 8 is a schematic cross-sectional view illustrating a portion of the other light detector according to the embodiment;

FIG. 9 is a schematic cross-sectional view illustrating a portion of another light detector according to the embodiment;

FIG. 10 is a schematic cross-sectional view illustrating a portion of another light detector according to the embodiment;

FIG. 11 is a schematic plan view illustrating the portion of the other light detector according to the embodiment;

FIG. 12 is a schematic view illustrating an active quenching circuit;

FIG. 13 is a schematic view illustrating a lidar (Laser Imaging Detection and Ranging (LIDAR)) device according to the embodiment;

FIG. 14 describes the detection of the detection object of the lidar device; and

FIG. 15 is a schematic top view of a mobile body that includes the lidar device according to the embodiment.

### DETAILED DESCRIPTION

A light detector according to one embodiment, includes an element region, a light concentrator, a structure part and a light-shielding part. The element region includes a first semiconductor region of a first conductivity type, and a second semiconductor region of a second conductivity type. The light concentrator is separated from the element region in a first direction. The light concentrator is configured to concentrate light incident on the light concentrator. The structure part is arranged with the element region in a direction crossing the first direction. The structure part has a different refractive index from the element region. The light-shielding part is located between the element region and the light concentrator. The light-shielding part includes an opening. At least a portion of the light incident on the light concentrator is able to be incident on the element region by passing through the opening.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

According to embodiments, a first conductivity type is one of a p-type or an n-type. A second conductivity type is the other of the p-type or the n-type. In the following description, the first conductivity type is the n-type, and the second conductivity type is the p-type.

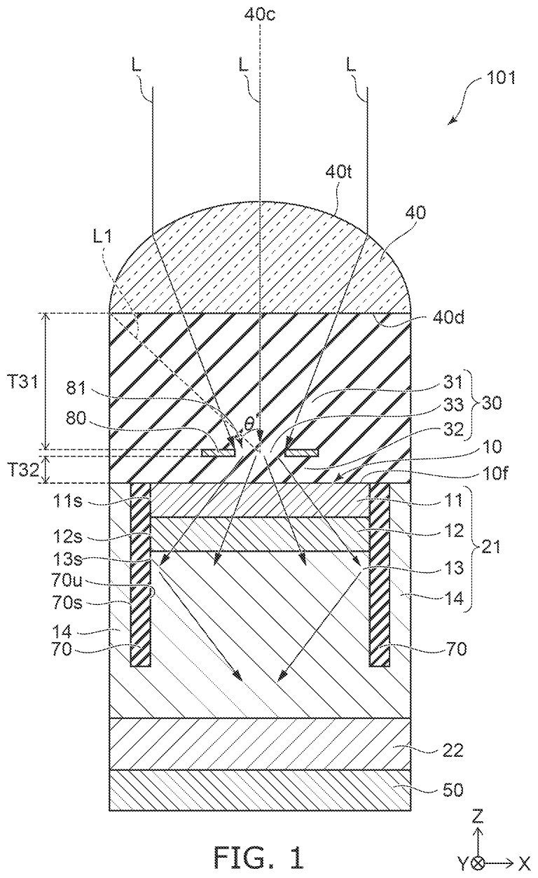

FIG. 1 is a schematic cross-sectional view illustrating a light detector according to an embodiment.

As illustrated in FIG. 1, the light detector 101 according to the embodiment includes an element region 10 (a light-receiving element), a structure part 70, a light-shielding part 80, and a light concentrator 40. The light-shielding part 80 is located between the element region 10 and the light concentrator 40. In the example, the light detector 101 further includes an outer perimeter region 14 and an insulating layer 30.

In the description of the embodiments, the direction from the element region 10 toward the light concentrator 40 is taken as a Z-axis direction (a first direction). A direction perpendicular to the Z-axis direction is taken as an X-axis direction (a second direction). A direction perpendicular to the Z-axis direction and the X-axis direction is taken as a Y-axis direction (a third direction). In the description, the direction from the element region 10 toward the light concentrator 40 is called “up”, and the opposite direction is called “down”. These directions are based on the relative positional relationship between the element region and the light concentrator 40 and are independent of the direction of gravity. “Up” corresponds to the side at which the light concentrator 40 is mounted and at which light is incident on the light detector.

In the example of FIG. 1, the light detector 101 further includes an electrode 50 and a semiconductor layer 22 located under the element region 10. The electrode 50 is, for example, a back electrode. The semiconductor layer 22 is located on the electrode 50 and is electrically connected with the electrode 50. The semiconductor layer 22 is, for example, a semiconductor substrate of the second conductivity type.

The element region 10 includes a first semiconductor region 11, a second semiconductor region 12, and a third semiconductor region 13. The third semiconductor region 13 is located on the semiconductor layer 22 and contacts the semiconductor layer 22. The third semiconductor region 13 is of the second conductivity type and is electrically connected with the semiconductor layer 22.

The second semiconductor region 12 is located on the third semiconductor region 13 and contacts the third semiconductor region 13. The second semiconductor region 12 is of the second conductivity type and is electrically connected with the third semiconductor region 13. The second-conductivity-type impurity concentration of the second semiconductor region 12 is greater than the second-conductivity-type impurity concentration of the third semiconductor region 13.

The first semiconductor region 11 is located on the second semiconductor region 12 and contacts the second semiconductor region 12. The first semiconductor region 11 is of the first conductivity type and is electrically connected with the second semiconductor region 12.

For example, the first semiconductor region 11, the second semiconductor region 12, and the third semiconductor region 13 are included in one semiconductor layer 21. A p-n junction is formed at the interface between the first semiconductor region 11 and the second semiconductor region 12. A photodiode is formed of the first and second semiconductor regions 11 and 12 (and the third semiconductor region 13). The photodiode (the element region 10) includes a light-receiving surface 10f. The light-receiving surface 10f is the upper surface of the first semiconductor region 11.

The structure part 70 is arranged with the element region in a direction crossing the Z-axis direction. The structure part 70 is, for example, a structure body located inside a trench in which the semiconductor layer 21 is located. The structure part 70 surrounds the element region. The structure part 70 is, for example, ring-shaped. An inner surface 70u of the structure part 70 contacts a side surface 11s of the first semiconductor region 11, a side surface 12s of the second semiconductor region 12, and a side surface 13s of the third semiconductor region 13. The surface area of the light-receiving surface 10f can be increased thereby. However, the inner surface 70u may be separated from at least one of the side surface 11s, the side surface 12s, or the side surface 13s.

The structure part 70 includes a different material from the regions of the semiconductor layer 21 (the first semiconductor region 11, the second semiconductor region 12, the third semiconductor region 13, etc.). The refractive index of the structure part 70 is different from the refractive indexes of the regions of the semiconductor layer 21. The refractive index of the structure part 70 is different from the refractive index of the element region 10. That is, the refractive index of the structure part 70 is different from the refractive indexes of the first to third semiconductor regions 11 to 13. The structure part 70 is insulative. At least a portion of the trench interior (the structure part 70) may be hollow.

The outer perimeter region 14 (a fourth semiconductor region) includes a semiconductor and is, for example, a portion of the semiconductor layer 21. The outer perimeter region 14 surrounds the element region 10 and the structure part 70. The outer perimeter region 14 includes, for example, a ring-shaped portion. The structure part 70 is positioned between the outer perimeter region 14 and the element region 10. The outer perimeter region 14 contacts an outer side surface 70s of the structure part 70.

The outer perimeter region 14 and the third semiconductor region 13 are continuous with each other via a portion of the semiconductor layer 21 below the structure part 70. For example, the outer perimeter region 14 is of the second conductivity type and is electrically connected with the third semiconductor region 13 and the electrode 50. The second-conductivity-type impurity concentration of the outer perimeter region 14 may be equal to the second-conductivity-type impurity concentration of the third semiconductor region 13.

The light-shielding part 80 is located on the element region and is separated from the element region 10. The light-shielding part 80 includes an opening 81. For example, the opening 81 extends through the light-shielding part 80 in the Z-axis direction. The light-shielding part 80 shields the travel of light incident on the light-shielding part 80 (the portion other than the opening 81).

The light-shielding part 80 may shield light by at least one of reflecting or absorbing light. The shielding of light does not always completely shield the light incident on the light-shielding part 80. For example, the transmittance for the incident light of the light-shielding part 80 is less than the transmittance for the incident light of the semiconductor layer 21, less than the transmittance for the incident light of the insulating layer 30, and less than the transmittance for the incident light of the light concentrator 40. The transmittance for the incident light of the light-shielding part 80 is, for example, not less than 0% and not more than 70%, and may be not more than 20% or not more than 10%.

For example, the reflectance to the incident light of the light-shielding part 80 is greater than the reflectance to the incident light of the semiconductor layer 21, greater than the reflectance to the incident light of the insulating layer 30, and greater than the reflectance to the incident light of the light concentrator 40. The reflectance to the incident light of the light-shielding part 80 is, for example, not less than 30% and not more than 100%, and may be not less than 80% or not less than 90%.

The incident light is, for example, near-infrared light. The wavelength of the near-infrared light is, for example, not less than 0.7 micrometers (μm) and not more than 2.5 μm. However, according to the embodiment, the incident light may not always be near-infrared light.

The light concentrator 40 is located on the light-shielding part 80 and is separated from the light-shielding part 80. For example, the light concentrator 40 is an upwardly convex lens (e.g., a microlens). A lower surface 40d of the light concentrator has a planar shape extending along the X-Y plane. An upper surface 40t of the light concentrator 40 is an upwardly convex curved surface. The light concentrator 40 is configured to concentrate the light that is incident. For example, the light concentrator 40 concentrates at least a portion of the light incident on the light concentrator 40 toward the opening 81. In other words, the light concentrator 40 refracts at least a portion of the incident light toward the opening 81.

The insulating layer 30 is located between the semiconductor layer 21 and the light concentrator 40. The insulating layer 30 contacts the surface of the semiconductor layer 21. In other words, the insulating layer 30 contacts the element region 10 (the first semiconductor region 11), the structure part 70, and the outer perimeter region 14. The insulating layer 30 contacts the lower surface 40d of the light concentrator 40.

A portion of the insulating layer 30 is positioned around the light-shielding part 80 and contacts the light-shielding part 80. In other words, the light-shielding part 80 is located inside the insulating layer 30. More specifically, the insulating layer 30 includes a first insulating part 31, a second insulating part 32, and a third insulating part 33. The first insulating part 31 is positioned between the light-shielding part 80 and the light concentrator 40 and contacts the light-shielding part 80 and the light concentrator 40. The second insulating part 32 is positioned between the light-shielding part 80 and the element region 10 and contacts the light-shielding part 80 and the element region 10. The third insulating part 33 is located in the opening 81 between the first insulating part 31 and the second insulating part 32 and contacts the first insulating part 31, the second insulating part 32, and the inner perimeter surface of the light-shielding part 80.

In the example, the light-shielding part 80 is electrically insulated from the other interconnects (a first interconnect 51 described below, etc.) by the insulating layer 30.

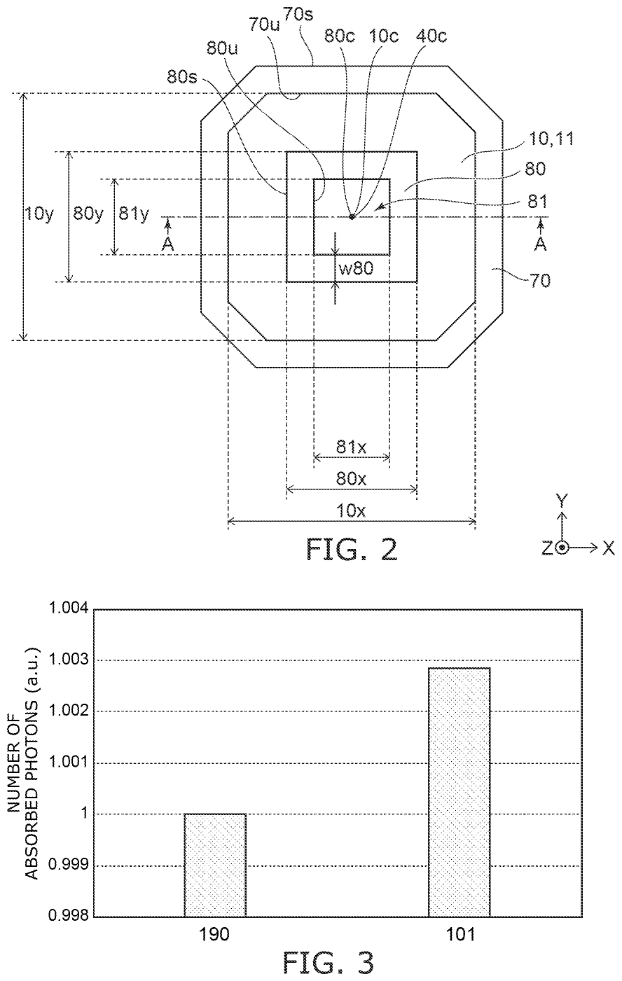

FIG. 2 is a schematic plan view illustrating a portion of the light detector according to the embodiment.

FIG. 2 illustrates the light detector 101 shown in FIG. 1 when viewed from above. FIG. 1 corresponds to a line A-A cross section of FIG. 2. Some of the components such as the light concentrator 40, the outer perimeter region 14, etc., are not illustrated in FIG. 2. In the example as illustrated in FIG. 2, the structure part 70 has an octagonal ring shape that surrounds the element region 10.

The opening 81 may overlap a center 10c of the element region 10 in the Z-axis direction. For example, the position of a center 80c of the opening 81 matches the position of the center 10c of the element region 10 in the X-Y plane. The opening 81 is arranged with (overlaps) a center 40c (the optical axis) of the light concentrator 40 in the Z-axis direction. For example, the position of the center 80c of the opening 81 matches the position of the center 40c of the light concentrator 40 in the X-Y plane. In the description above, the “center” may be the centroid of the planar shape when viewed from above.

In the example, the light-shielding part 80 has a quadrilateral ring shape in which the opening 81 is provided. The light-shielding part 80 includes an inner perimeter surface 80u and an outer perimeter surface 80s. The inner perimeter surface 80u and the outer perimeter surface 80s are surfaces that cross the X-Y plane along the Z-axis direction.

The inner perimeter surface 80u defines the opening 81. In other words, the inner perimeter surface 80u is a surface that defines the opening 81; and the region inside the inner perimeter surface 80u is the opening 81. For example, the inner perimeter surface 80u continuously surrounds the opening 81. That is, the inner perimeter surface 80u is a continuous ring shape without breaks when viewed from above. The opening 81 is circular or polygonal when viewed from above. In the example, the inner perimeter surface 80u and the opening 81 are quadrilateral when viewed from above.

The outer perimeter surface 80s is separated from the inner perimeter surface 80u in the X-Y plane and continuously surrounds, for example, the inner perimeter surface 80u and the outer side of the opening 81. That is, the outer perimeter surface 80s has a ring shape that surrounds the opening 81 and the inner perimeter surface 80u without breaks when viewed from above. In the example, the outer perimeter surface 80s is a quadrilateral along the inner perimeter surface 80u when viewed from above. For example, a width W80 of the light-shielding part 80 (the length from the inner perimeter surface 80u to the outer perimeter surface 80s) is constant. The width W80 is, for example, not less than 0.1 μm and not more than 1.0 μm.

Thus, in the example, the shapes of the inner perimeter surface 80u and the outer perimeter surface 80s each are closed linear shapes when viewed from above. However, according to the embodiment, the light-shielding part 80 (the inner perimeter surface 80u and the outer perimeter surface 80s) are not limited to continuous ring shapes without breaks, and may be discontinuous ring shapes (continuous ring shapes missing portions), or may not be ring shapes.

The light-shielding part 80 is arranged with (overlaps) the element region 10 in the Z-axis direction. The light-shielding part 80 is not arranged with (does not overlap) the structure part 70 and the outer perimeter region 14 in the Z-axis direction. At least a portion of the outer perimeter surface 80s of the light-shielding part 80 overlaps the element region 10 in the Z-axis direction. For example, the entire outer perimeter surface 80s of the light-shielding part 80 is positioned inward of the inner surface 70u of the structure part 70 when viewed from above. The length (the outer diameter) along the X-axis direction of the light-shielding part 80 is less than the length (the outer diameter) along the X-axis direction of the element region 10.

For example, a length 81x in the X-axis direction of the opening 81 is equal to a length 81y in the Y-axis direction of the opening 81. For example, a length 80x in the X-axis direction of the light-shielding part 80 is equal to a length 80y in the Y-axis direction of the light-shielding part 80. For example, a length 10x in the X-axis direction of the element region 10 is equal to a length 10y in the Y-axis direction of the element region 10. The length 81x is, for example, not less than 0.7 μm and not more than 12 μm. The length 80x is, for example, not less than 0.8 μm and not more than 13 μm. The length 10x is, for example, not less than 4 μm and not more than 25 μm.

According to the embodiment, “match (same or equal)” includes not only an exact match (exactly the same or equal) but also a substantial match (substantially the same or equal). For example, the scope of “match (same or equal)” includes differences caused by fluctuation of process conditions.

According to the embodiment, “ring-shaped” includes not only a circular exterior form of the planar shape when viewed from above, but also polygonal. The scope of “circular” includes not only a perfect circle but also an ellipse, a flattened circle, a circle having at least a portion that is distorted, etc. The scope of “polygonal” includes polygonal with curved (rounded) corners. In other words, “polygonal” may be a shape that includes multiple sides (straight lines) and curves connecting the sides to each other. The scope of “ring-shaped” may include not only a continuous ring shape without breaks, but also circular or polygonal (e.g., substantially C-shaped) with one or more breaks.

According to the embodiment, “surround” includes not only the case where an unbroken component continuously surrounds another component, but also the case where multiple components are separated from each other and arranged around the other component. For example, the other component can be considered to be surrounded with the multiple components when the other component is positioned inside a path obtained by tracing along the multiple components. The other component can be considered to be surrounded with a circular shape or a polygon when the other component is positioned inside a circular shape or a polygon having one or more breaks when viewed in plan from above.

Materials of the components of the light detector 101 will now be described.

The semiconductor layer 21 (the first semiconductor region 11, the second semiconductor region 12, the third semiconductor region 13, and the outer perimeter region 14) and the semiconductor layer 22 include at least one semiconductor material selected from the group consisting of silicon, silicon carbide, gallium arsenide, and gallium nitride. For example, the semiconductor layer 21 and the semiconductor layer 22 include silicon. For example, the first-conductivity-type impurity concentration of the semiconductor layer 22 is greater than the second-conductivity-type impurity concentration of the third semiconductor region 13. For example, the second semiconductor region 12 is obtained by implanting boron as a p-type impurity into silicon. For example, the first semiconductor region 11 is obtained by implanting phosphorus, arsenic, or antimony as the n-type impurity into silicon. The semiconductor layer 21 is, for example, an epitaxial layer formed on a substrate.

The structure part 70 includes a different material from the materials of the element region 10 and the outer perimeter region 14. Specifically, the structure part 70 includes an insulating material. For example, the structure part 70 includes silicon and one selected from the group consisting of oxygen and nitrogen. For example, the structure part 70 includes silicon oxide or silicon nitride. The structure part 70 may have a stacked structure.

The light-shielding part 80 includes, for example, a metal material. The light-shielding part 80 includes, for example, at least one selected from the group consisting of titanium, tungsten, copper, and aluminum. The light-shielding part 80 is, for example, conductive. In the example, the light-shielding part 80 is formed of aluminum and is a metal mask that shields the incident light by reflecting. The light-shielding part 80 may include a high refractive index material other than a metal. The light-shielding part 80 may include, for example, at least one of amorphous silicon, germanium, or titanium nitride (TiN).

The light concentrator 40 includes a light-transmissive material. For example, the light concentrator 40 includes a light-transmissive resin such as an acrylic resin, etc.

The insulating layer 30 includes, for example, a light-transmissive material. For example, the insulating layer 30 includes silicon and one selected from the group consisting of oxygen and nitrogen. For example, the insulating layer 30 includes at least one of silicon oxide or silicon nitride.

The electrode 50 includes, for example, at least one metal selected from the group consisting of titanium, tungsten, copper, gold, aluminum, indium, and tin. This is similar for a conductive part 61, a pad 55, and the interconnects described below as well.

Operations of the light detector 101 will now be described.

As illustrated in FIG. 1, at least a portion of incident light L that is incident on the upper surface 40t of the light concentrator 40 from above is concentrated toward the opening 81 of the light-shielding part 80. In other words, at least a portion of the incident light L passes through the light concentrator 40 and a portion of the insulating layer 30 and travels toward the opening 81. At least a portion of the incident light L concentrated toward the opening 81 by the light concentrator 40 is incident on the element region 10 by passing through the opening 81. At least a portion of the incident light L that is incident on the element region 10 is reflected (e.g., undergoes total internal reflection) by the structure part 70 at the interface between the structure part 70 and the element region 10 and further travels through the element region 10.

For example, the element region 10 functions as a p-i-n diode or an avalanche photodiode. A charge is generated in the semiconductor layer 21 when the light is incident on the element region 10. When the charge is generated, a current flows in the interconnects and the like (e.g., the conductive part 61, a quenching part 63, and the first interconnect 51 described below) that are electrically connected with the first semiconductor region. The incidence of the light on the element region 10 can be detected by detecting the current flowing in the interconnects and the like as an output.

The conductive part 61 and the electrode 50 drive the light-receiving element by applying a voltage to the first and second semiconductor regions 11 and 12. The voltage can be applied between the first semiconductor region 11 and the second semiconductor region 12 by controlling the potential of the electrode 50. A reverse voltage that is greater than the breakdown voltage may be applied between the first semiconductor region 11 and the second semiconductor region 12. In other words, the element region 10 may include an avalanche photodiode that operates in a Geiger mode. By operating in a Geiger mode, a pulse signal of a high multiplication factor (i.e., a high gain) is output. The light-receiving sensitivity of the light detector can be increased thereby.

FIG. 3 is a graph illustrating characteristics of light detectors.

The vertical axis of FIG. 3 is number of photons absorbed per prescribed interval of the semiconductor layer (arbitrary units (a.u.)). A high number of absorbed photons corresponds to a high photon detection efficiency. FIG. 3 shows simulation results of a light detector 190 according to a reference example and the light detector 101 according to the embodiment. The light detector 190 has the configuration of the light detector 101 without the light-shielding part 80.

As illustrated in FIG. 3, the number of absorbed photons of the light detector 101 is greater than the number of absorbed photons of the light detector 190. The photon detection efficiency is increased by including the light-shielding part 80.

For example, according to the embodiment, the incident light L that passes through the opening 81 of the light-shielding part 80 is diffracted and spreads around below the light-shielding part 80. That is, the light-shielding part 80 that includes the opening 81 functions as a diffracting part that diffracts the incident light. For example, the incident angle of the incident light L with respect to the element region 10 is increased thereby. Therefore, the incident light L travels in a direction more tilted with respect to the Z-axis direction inside the element region 10 and is more easily incident on the structure part 70. Then, a portion of the incident light L that is incident on the structure part 70 is reflected by the structure part 70 and travels further through the element region 10. As a result, the optical path length of the incident light L inside the element region 10 can be increased, and the detection efficiency can be increased. For example, the quantum efficiency and the photon detection efficiency can be increased.

As described above, the opening 81 may be arranged with at least one of the center 40c of the light concentrator 40 or the center 10c of the element region 10 in the Z-axis direction. The inner perimeter surface 80u of the opening 81 is ring-shaped when viewed along the Z-axis direction. Thereby, for example, the light that is diffracted by passing through the opening 81 is easily spread isotropically with respect to the element region 10; and light is easily detected efficiently in a relatively wide area of the element region 10.

It is desirable for the distance in the Z-axis direction between the lens (the light concentrator 40) and the light-shielding part 80, i.e., a thickness T31 along the Z-axis direction of the first insulating part 31 (see FIG. 1), to be adjusted by the focal length and/or numerical opening of the lens. For example, the thickness T31 is not less than f−λ/NA² and not more than f+λ/NA². Here, f is the focal length of the lens, λ is the wavelength of the light (the incident light L), and NA is the numerical opening of the lens. NA is n sin θ. n is the refractive index of the first insulating part 31. θ is the angle between the optical axis of the lens and a light ray L1 (see FIG. 1). The light ray L1 passes through a point on the optical axis of the lens and the outermost side of the lens within the effective opening diameter. Thus, by adjusting the thickness T31 of the first insulating part 31, the light that passes through the light concentrator 40 is more easily concentrated toward the opening 81. For example, the light-shielding part 80 is located at the position at which the incident light L is concentrated by the lens; and more light can pass through the opening 81.

The second insulating part 32 is located between the light-shielding part 80 and the element region 10; and the light-shielding part 80 is separated from the element region 10. By ensuring the distance between the light-shielding part 80 and the element region 10, for example, the incident light L that is diffracted by the opening 81 spreads and is more easily incident on the element region 10. For example, the optical path length of the incident light L inside the element region 10 can be increased thereby.

On the other hand, as illustrated in FIG. 1, a thickness T32 along the Z-axis direction of the second insulating part 32 is less than the thickness T31. For example, by reducing the distance between the light-shielding part 80 and the element region 10 by reducing the thickness T32, the light that is diffracted by the opening 81 is prevented from being incident on the outer perimeter region 14 due to excessive spreading, and thereby is more easily incident on the element region 10.

The light-shielding part 80 includes a metal. Thereby, for example, a portion of the light reflected upward at the interface between the element region 10 and the second insulating part 32 can be reflected by the light-shielding part 80; and the portion of the light can again travel downward. Accordingly, the detection efficiency can be increased. Also, by providing the electrode 50 below the element region 10, a portion of the light that is incident on the electrode 50 by passing through the element region 10 can be reflected toward the element region 10 again.

In the example, the light-shielding part 80 is not arranged with the outer perimeter region 14 in the Z-axis direction. That is, the outer perimeter region 14 is not covered with the light-shielding part 80 from above. In such a case, light may be incident on the outer perimeter region 14 from above, and photoelectric conversion may occur in the outer perimeter region 14. For example, the output current of the light detector 101 is increased thereby, and the signal is more easily detected.

Furthermore, at least a portion of the outer perimeter surface 80s of the light-shielding part 80 is arranged with (overlaps) the element region 10 in the Z-axis direction. That is, at least a portion of the outer part of the element region 10 is not covered with the light-shielding part 80. Therefore, for example, even if a portion of the incident light L is not concentrated toward the light-shielding part 80 (the opening 81), some of that portion of light can be incident on the element region 10 by passing outside the light-shielding part 80.

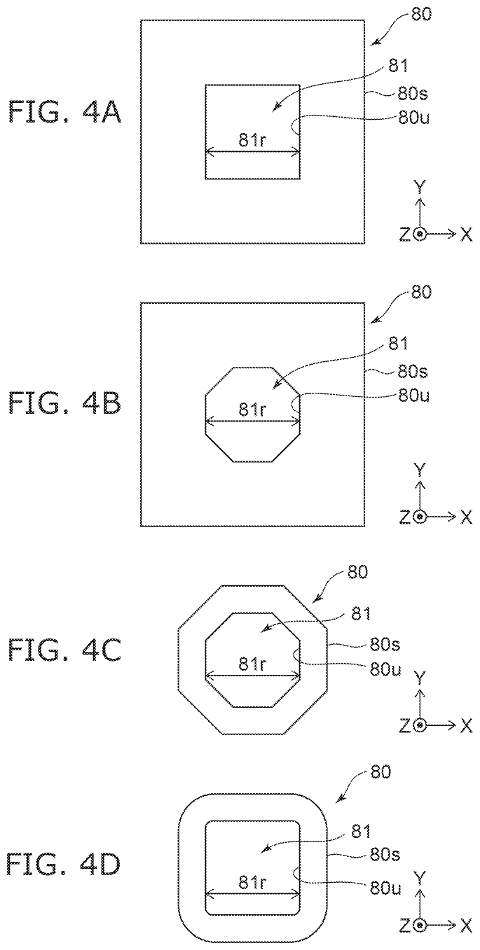

FIGS. 4A to 4D are schematic plan views illustrating light-shielding parts of the light detector according to the embodiment.

Similarly to FIG. 2, etc., the light-shielding part 80 (the inner perimeter surface 80u and the outer perimeter surface 80s) have quadrilateral ring shapes in FIG. 4A. For example, a diameter 81r of the opening 81 (the inner diameter of the light-shielding part 80) is adjusted according to the wavelength of the incident light L and the focal length of the lens (the light concentrator 40). For example, the diameter 81r is not less than the spot diameter (the focusing diameter) of the lens. Specifically, for example, the spot diameter of the lens is calculated to be about 1.22λ/NA. That is, the diameter 81r is, for example, not less than 1.22λ/NA. Here, λ is the wavelength of the incident light L, and NA is the numerical opening of the lens. By setting the diameter 81r of the opening 81 to be not less than 1.22λ/NA, more of the light concentrated toward the opening 81 can be diffracted by passing through the opening 81. The diameter 81r is, for example, not more than the diameter of the element region 10.

When the shape is a polygon when viewed along the Z-axis direction, the diameter is the length of the polygon measured along a direction in the X-Y plane perpendicular to one side of the polygon. When the shape is a circle when viewed along the Z-axis direction, the diameter is the length of the circle measured along a direction in the X-Y plane. When the diameter is different according to the direction in the X-Y plane in which the length is measured, the maximum value is used as the diameter.

FIGS. 4B to 4D illustrate other shapes of the light-shielding part 80. In FIG. 4B, the shape of the inner perimeter surface 80u (the shape of the opening 81) is octagonal; and the shape of the outer perimeter surface 80s is quadrilateral. In FIG. 4C, the shape of the inner perimeter surface 80u and the shape of the outer perimeter surface 80s are octagonal. In FIG. 4D, the shape of the inner perimeter surface 80u and the shape of the outer perimeter surface 80s are rounded quadrilaterals. Thus, the inner perimeter surface 80u and the outer perimeter surface 80s may have different shapes, and may be polygons with curvature at the corners.

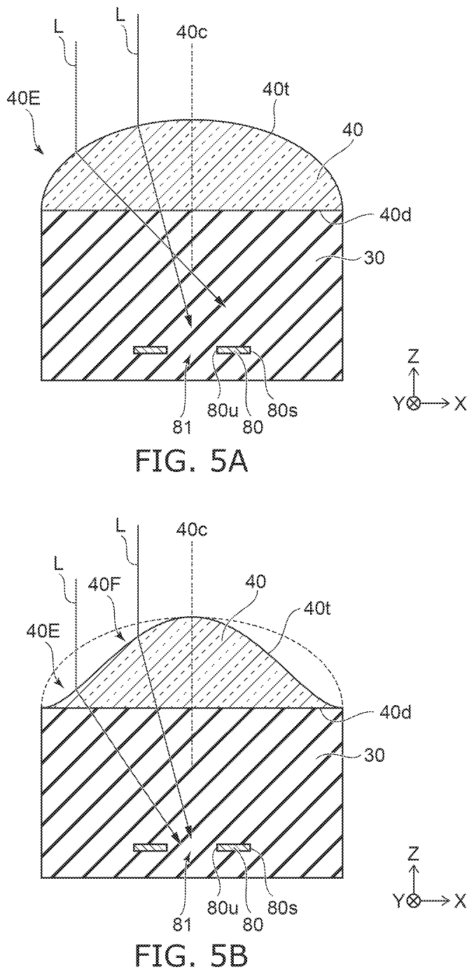

FIGS. 5A and 5B are schematic cross-sectional views illustrating a portion of the light detector according to the embodiment.

These drawings illustrate the light concentrator 40, the light-shielding part 80, and the insulating layer 30 of the light detector 101. FIG. 5A illustrates the light concentrator 40 with a shape similar to the light concentrator 40 shown in FIG. 2. FIG. 5B illustrates another shape of the light concentrator 40.

As illustrated in FIG. 5A, for example, the light concentrator 40 is thickest at the center 40c (the optical axis) in the X-Y plane. The thickness of the light concentrator 40 decreases from the center 40c toward an end portion 40E in the X-Y plane. For example, the light concentrator 40 illustrated in FIGS. 5A and 2 may be a spherical lens in which the upper surface 40t has a constant curvature.

In FIG. 5B, the curvature of the upper surface 40t changes from the center 40c toward the end portion 40E. Thus, the light concentrator 40 may be an aspherical lens. For example, the curvature of the upper surface 40t at the center 40c is greater than the curvature of the upper surface 40t at an outer portion 40F of the center 40c.

In the spherical lens, there are cases where a portion of the incident light L that is incident on the upper surface 40t may not pass through the opening 81 due to spherical aberration. In contrast, for example, by using the aspherical lens, more of the incident light L can be concentrated toward the opening 81.

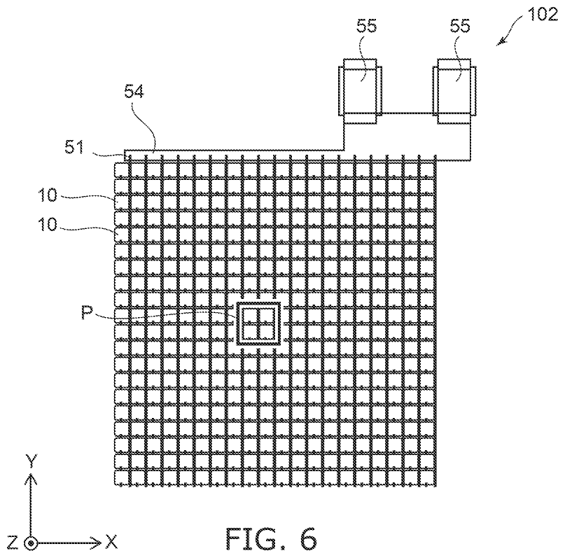

FIG. 6 is a schematic plan view illustrating another light detector according to the embodiment.

A light detector 102 illustrated in FIG. 6 includes multiple element structures similar to the structure described with reference to FIG. 1, etc. The multiple element structures are arranged in an array configuration along the X-Y plane. For example, the multiple element structures are arranged periodically at a uniform pitch in the X-axis direction and the Y-axis direction. In other words, the light detector 102 includes the electrode 50, the semiconductor layer 22, the multiple element regions 10, the multiple structure parts 70, the multiple outer perimeter regions 14, the multiple light-shielding parts 80, the multiple light concentrators 40 (the microlens array), and the insulating layer 30. However, as described below, the shape of the light-shielding part 80 of the light detector 102 is different from that of the light detector 101. The light detector 102 further includes a contact 67 and the contact 67 and a conductive part 68 described below. Between the element structures that are next to each other, the electrodes 50 are continuous with each other, the semiconductor layers 21 are continuous with each other, the semiconductor layers 22 are continuous with each other, and the insulating layers 30 are continuous with each other.

As shown in FIG. 6, the light detector 102 further includes the multiple first interconnects 51, a common line 54, and the pad 55 (a first electrode). One first interconnect 51 is electrically connected to the multiple element regions 10 arranged in the Y-axis direction. The multiple first interconnects 51 that are arranged in the X-axis direction are electrically connected with the common line 54. The common line 54 is electrically connected with not less than one pad 55. An interconnect of an external device is electrically connected to the pad 55.

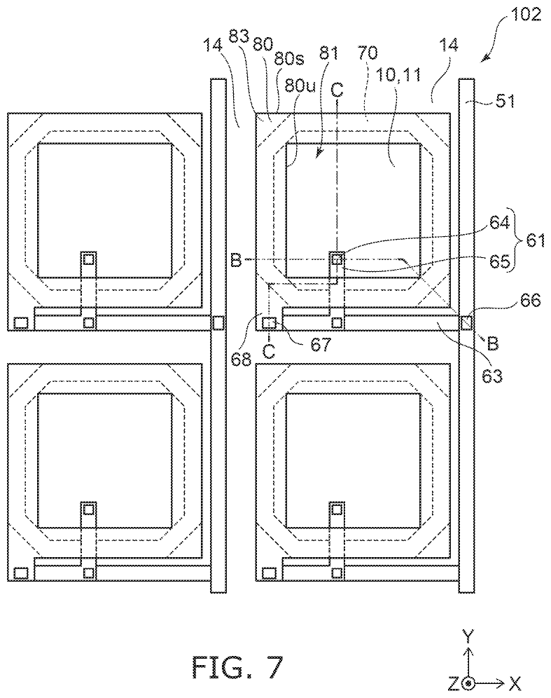

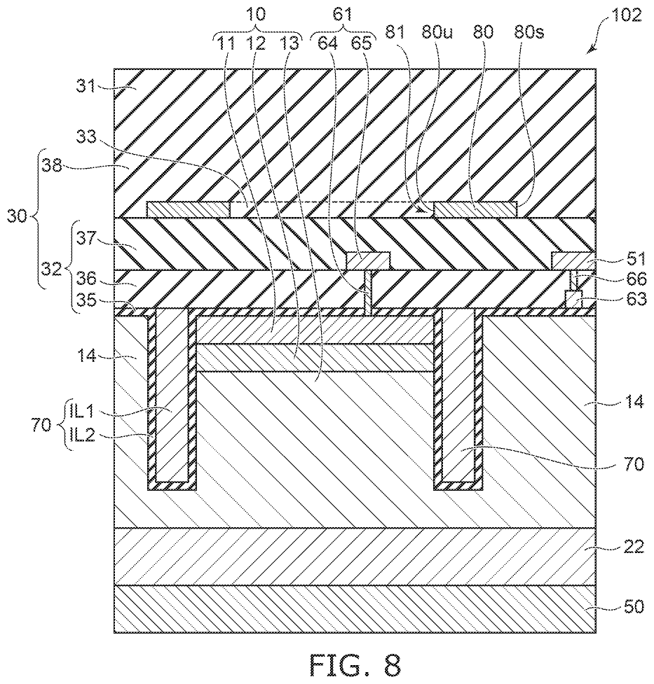

FIG. 7 is a schematic plan view illustrating a portion of another light detector according to the embodiment.

FIG. 8 is a schematic cross-sectional view illustrating a portion of the other light detector according to the embodiment.

FIG. 7 shows an enlarged portion P of the light detector 102 shown in FIG. 6. Some of the components such as the light concentrator 40, the insulating layer 30, etc., are not illustrated in FIG. 7.

FIG. 8 corresponds to a line B-B cross section shown in FIG. 7. The light concentrator 40 is not illustrated in FIG. 8.

As illustrated in FIG. 7, the light detector 102 further includes the conductive part 61 and the quenching part 63. The conductive part 61 is located on the first semiconductor region 11 and contacts the first semiconductor region 11. The conductive part 61 is electrically connected with the first semiconductor region 11. At least a portion of the conductive part 61 may be located inside the insulating layer 30.

For example, the quenching part 63 exists at a different position from the first semiconductor region 11 when viewed from the Z-axis direction. For example, the quenching part 63 is arranged with the structure part 70 or the outer perimeter region 14 in the Z-axis direction.

The quenching part 63 is electrically connected with the conductive part 61. Thereby, one end of the quenching part 63 is electrically connected with the first semiconductor region 11 via the conductive part 61. Multiple quenching parts 63 are included, and the multiple quenching parts 63 are electrically connected respectively with the multiple first semiconductor regions 11. Another end of the quenching part 63 is electrically connected with the first interconnect 51.

The quenching part 63 is provided to suppress the continuation of avalanche breakdown when light is incident on the element region 10 and avalanche breakdown occurs. When avalanche breakdown occurs and a current flows in the quenching part 63, a voltage drop that corresponds to the electrical resistance of the quenching part 63 occurs. The potential difference between the first semiconductor region 11 and the second semiconductor region 12 is reduced by the voltage drop; and the avalanche breakdown stops. The next light that is incident on the element region 10 can be detected thereby.

In the example, a quenching resistance is electrically connected to each element region 10 as the quenching part 63. The resistance of the quenching part 63 is, for example, not less than 50 kΩ and not more than 6 MΩ. The quenching resistance includes, for example, polysilicon as a semiconductor material. An n-type impurity or a p-type impurity may be added to the quenching resistance.

As illustrated in FIG. 8, the structure part 70 may include a first insulating layer IL1 and a second insulating layer IL2. The second insulating layer IL2 is located between the first insulating layer IL1 and the element region 10 and between the first insulating layer IL1 and the semiconductor layer 22. For example, the first insulating layer IL1 and the second insulating layer IL2 include silicon oxide; and the second insulating layer IL2 has a dense structure compared to the first insulating layer IL1.

The multiple conductive parts 61 are connected respectively to the multiple element regions 10. Each of the multiple conductive parts 61 includes a contact 64 and a connection interconnect 65. The quenching part 63 is electrically connected with the first semiconductor region 11 via the contact 64 and the connection interconnect 65, and is electrically connected with the first interconnect 51 via a contact 66.

The contacts 64 and 66 include a metal material. For example, the contacts 64 and 66 include at least one selected from the group consisting of titanium, tungsten, copper, and aluminum. The contacts 64 and 66 may include a conductive body made of a silicon compound or a nitride of at least one selected from the group consisting of titanium, tungsten, copper, and aluminum.

For example, the position in the Z-axis direction of the quenching part 63 is between the position in the Z-axis direction of the first semiconductor region 11 and the position in the Z-axis direction of the first interconnect 51. The electrical resistance of the quenching part 63 is greater than the electrical resistances of the conductive part 61, the contact 64, the contact 66, and the connection interconnect 65.

For example, the insulating layer 30 includes insulating films 35 to 38. The insulating film 35 is located on the element region 10 and the outer perimeter region 14. The insulating film 36 is located on the insulating film 35. The insulating film 37 is located on the insulating film 36. The insulating film 38 is located on the insulating film 37. The second insulating part 32 described above includes the insulating films 35 to 37. The first insulating part 31 and the third insulating part 33 described above each are, for example, portions of the insulating film 38. The insulating films also may have stacked structures as appropriate.

The contact 64 is arranged with the insulating films 35 and 36 in a direction perpendicular to the Z-axis direction. The side surface (the surface along the Z-axis direction) of the contact 64 is surrounded with and in contact with the insulating films 35 and 36.

The quenching part 63 and the contact 66 are arranged with the insulating film 36 in a direction perpendicular to the Z-axis direction. The side surface (the surface along the Z-axis direction) of the quenching part 63 and the side surface (the surface along the Z-axis direction) of the contact 66 each are surrounded with and in contact with the insulating film 36. A portion of the insulating film 35 is located between the outer perimeter region 14 and the quenching part 63 in the Z-axis direction.

The first interconnect 51 and the connection interconnect 65 each are positioned between the insulating film 36 and the insulating film 37. The side surface (the surface along the Z-axis direction) of the first interconnect 51 and the side surface (the surface along the Z-axis direction) of the connection interconnect 65 are surrounded with and in contact with the insulating film 37.

The light-shielding part 80 is positioned between the insulating film 37 and the insulating film 38. The inner perimeter surface 80u and the outer perimeter surface 80s of the light-shielding part 80 each are surrounded with and in contact with the insulating film 38.

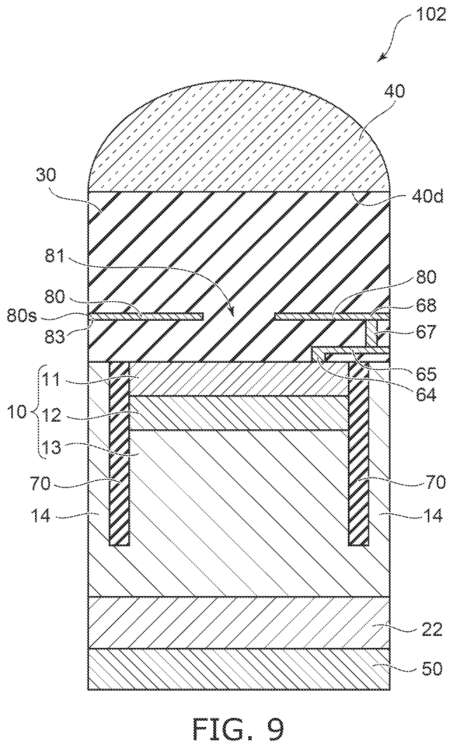

FIG. 9 is a schematic cross-sectional view illustrating a portion of another light detector according to the embodiment.

FIG. 9 corresponds to a line C-C cross section shown in FIG. 7. In the light detector 102, the outer diameter of the light-shielding part 80 (the diameter of the outer perimeter surface 80s) is greater than the diameter of the element region 10 and greater than the diameter of the structure part 70. That is, in the example as illustrated in FIG. 9, the light-shielding part 80 covers the entire structure part 70 and a portion of the outer perimeter region 14 from above. Thus, the light-shielding part 80 may overlap at least a portion of the outer perimeter region 14 in the Z-axis direction.

The light detector 102 further includes the contact 67 (the conductive part) and the conductive part 68. The contact 67 and the conductive part 68 electrically connect the light-shielding part 80 and the connection interconnect 65. The material of the contact 67 may be similar to that of the contact 64 or the contact 66. The material of the conductive part 68 may be similar to that of the light-shielding part 80. The conductive part 68 is continuous from the light-shielding part 80 and electrically connected with the light-shielding part 80. The conductive part 68 may be a portion of the light-shielding part 80 (a portion of the metal film forming the light-shielding part 80). One end of the contact 67 is connected with the connection interconnect 65; and another end of the contact 67 is connected with the conductive part 68. For example, the contact 67 extends in the Z-axis direction between the connection interconnect 65 and the conductive part 68. The lower end of the contact 67 contacts the connection interconnect 65; and the upper end of the contact 67 contacts the conductive part 68. The conductive part 68 may be omitted, and the connection interconnect 65 may be connected directly to the light-shielding part 80.

For example, the contact 67 exists at a different position from the first semiconductor region 11 when viewed from the Z-axis direction. For example, the contact 67 is arranged with (overlaps) the outer perimeter region 14 in the Z-axis direction.

In the light detector 102 as well, similarly to the description of the light detector 101, the optical path length of the incident light L inside the semiconductor layer 21 can be lengthened. The detection efficiency can be increased thereby.

Noise may be generated in the output when photoelectric conversion occurs in the outer perimeter region 14. In contrast, in the example, the light-shielding part 80 includes a portion 83 that is arranged with the outer perimeter region 14 in the Z-axis direction. The light that is incident on the outer perimeter region 14 from above can be suppressed thereby, and the noise can be suppressed.

In the example illustrated in FIG. 7, the multiple light-shielding parts 80 are separated from each other. The multiple light-shielding parts 80 are not limited thereto; the light-shielding parts 80 that are next to each other may be electrically connected by interconnects or may be continuous. For example, the light-shielding part 80 may be one metal film covering the multiple element regions 10. The multiple openings 81 are provided in such a metal film to correspond to the positions of the multiple element regions 10. For example, the light-shielding part 80 may overlap the entire outer perimeter region 14 and the entire structure part 70 in the Z-axis direction.

In the light detector 102 as described above, the light-shielding part 80 is electrically connected with the first interconnect 51. In such a case, for example, the apparent output is increased by the parasitic capacitance due to the light-shielding part 80. For example, the signal is more easily detected thereby. On the other hand, as in the light detector 101 described above, the light-shielding part 80 may be electrically insulated from the first interconnect 51. In such a case, the effects of the parasitic capacitance are suppressed, and the output can be stabilized.

As described with reference to FIGS. 8 and 9, the position in the Z-axis direction of the light-shielding part 80 is different from the position in the Z-axis direction of the first interconnect 51. That is, the light-shielding part 80 is located in a different layer from the first interconnect 51. For example, the layout and/or height of the light-shielding part 80 is easily adjusted thereby. For example, in the light detector 102, the light-shielding part 80 is positioned higher than the first interconnect 51. In such a case, the distance between the light-shielding part 80 and the element region 10 is easily ensured.

Conduction and optical interference between the element regions 10 that are next to each other can be suppressed by the structure part 70. For example, the structure part 70 suppresses the movement of secondary photons and carriers between the element regions 10. When light is incident on the element region 10 and secondary photons are generated, the secondary photons that travel toward the neighboring element regions 10 are reflected and refracted by the interface with the structure part 70. By including the structure part 70, the crosstalk noise can be reduced.

The multiple structure parts 70 are provided independently for each element. In other words, the multiple structure parts 70 are separated and do not physically contact each other. The number of interfaces of the structure part 70 between the element regions 10 that are next to each other is greater than when one separation structure is located between the element regions 10 that are next to each other. By increasing the number of interfaces, the secondary photons that travel toward the neighboring element regions 10 when secondary photons are generated in the element region 10 are more easily reflected. Crosstalk noise can be further reduced thereby. The outer perimeter region 14 is positioned between two structure parts 70 that are next to each other. For example, the outer perimeter region 14 extends in the Y-axis direction between the structure parts 70 that are next to each other in the X-axis direction. The outer perimeter region 14 extends in the X-axis direction between the structure parts 70 that are next to each other in the Y-axis direction.

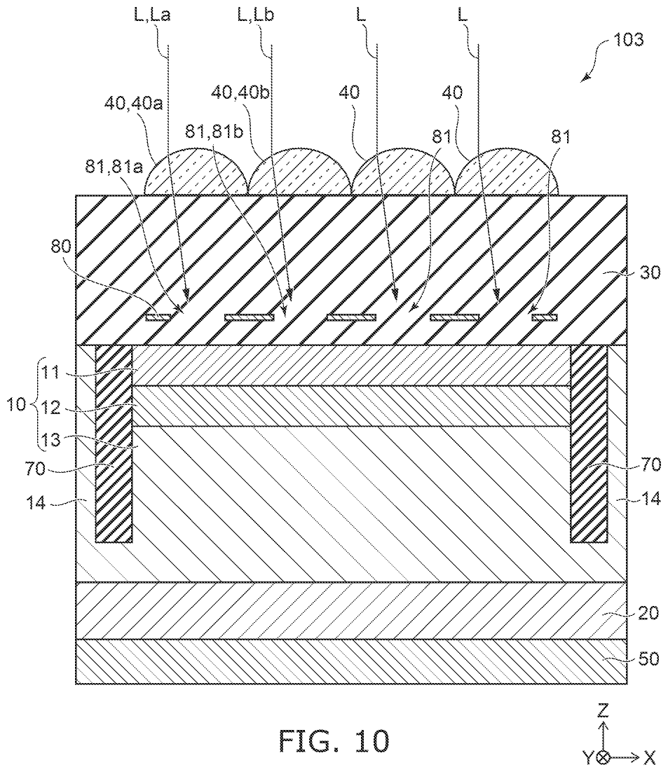

FIG. 10 is a schematic cross-sectional view illustrating a portion of another light detector according to the embodiment.

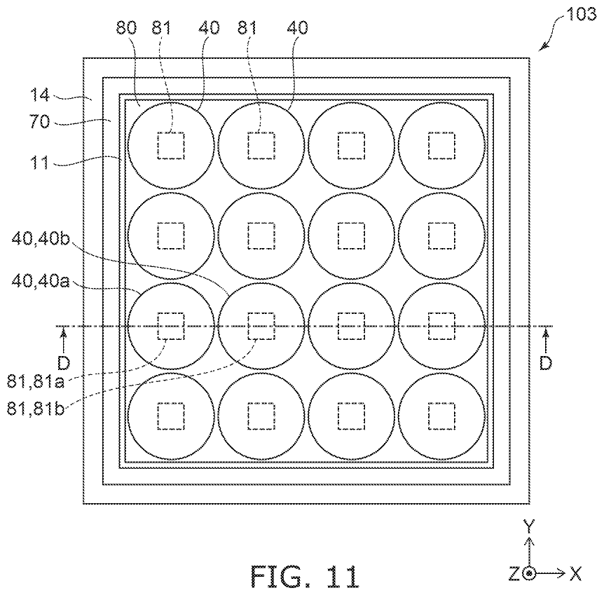

FIG. 11 is a schematic plan view illustrating the portion of the other light detector according to the embodiment.

FIGS. 10 and 11 illustrate the light detector 103 according to the embodiment. FIG. 10 corresponds to a line D-D cross section shown in FIG. 11. In the light detector 103, the multiple light concentrators 40 and the multiple openings 81 are located on one element region 10. Otherwise, a description similar to that of the light detector 101 or 102 is applicable to the light detector 103. The multiple light concentrators 40 may have the same shape. The multiple openings 81 may have the same shape.

The multiple openings 81 are provided in one light-shielding part 80 to correspond to the positions of the multiple light concentrators 40 (e.g., a compound-eye lens). In other words, the multiple openings 81 are positioned respectively between one element region 10 and the multiple light concentrators 40.

The multiple light concentrators 40 are arranged in an array configuration (a lattice shape) along the X-Y plane. For example, the multiple light concentrators 40 are arranged periodically at a uniform pitch in the X-axis direction and the Y-axis direction. One opening 81 is positioned under one light concentrator 40.

For example, the multiple light concentrators 40 include a first light concentrator 40a and a second light concentrator 40b as light concentrators 40. The multiple openings 81 include a first opening 81a and a second opening 81b as openings 81. In such a case, the first opening 81a is positioned between the element region 10 and the first light concentrator 40a. The second opening 81b is positioned between the element region 10 and the second light concentrator 40b.

The multiple light concentrators 40 concentrate at least a portion of the light that is incident on the multiple light concentrators 40 toward the multiple openings 81. For example, the first light concentrator 40a concentrates at least a portion of light La that is incident on the first light concentrator 40a toward the first opening 81a. Similarly, the second light concentrator 40b concentrates at least a portion of light Lb that is incident on the second light concentrator 40b toward the second opening 81b.

At least a portion of the light that is incident on the multiple light concentrators 40 is incident on the element region by passing through the multiple openings 81. For example, at least a portion of the light La concentrated toward the first opening 81a by the first light concentrator 40a is incident on the element region 10 by passing through the first opening 81a. Similarly, at least a portion of the light Lb concentrated toward the second opening 81b by the second light concentrator 40b is incident on the element region 10 by passing through the second opening 81b.

Compared to when one light concentrator 40 is located on one element region 10, the diameter of each light concentrator is smaller when the multiple light concentrators 40 are located on one element region 10. For example, the focal length of the light concentrator 40 can be reduced thereby. Therefore, for example, the distance between the light concentrator 40 and the light-shielding part 80 can be reduced, and the light detector can be thinner.

In the example as illustrated in FIG. 11, the multiple openings 81 are provided in one light-shielding part 80 (e.g., a metal film). The light-shielding part 80 is not limited thereto; for example, multiple light-shielding parts 80 that each include not less than one opening 81 may be included. For example, multiple ring-shaped metal films may be arranged along the X-Y plane as the light-shielding part 80 on one element region 10. In such a case, each metal film (light-shielding part 80) includes one opening 81.

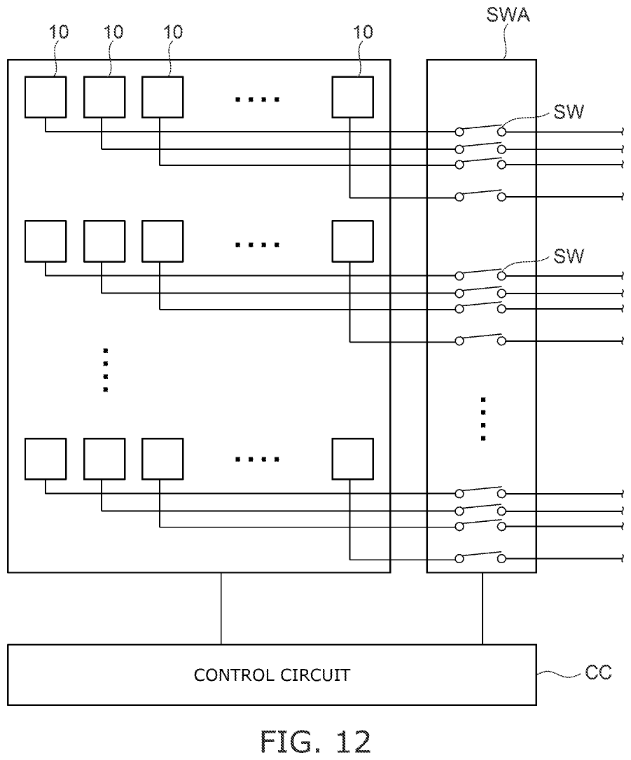

FIG. 12 is a schematic view illustrating an active quenching circuit.

In the light detector according to the embodiments described above, a resistor that generates a large voltage drop is included as the quenching part 63. In the light detector according to the embodiments, a control circuit and a switching element may be included instead of the resistor. In other words, an active quenching circuit for blocking the current is included as the quenching part 63.

As shown in FIG. 12, the active quenching circuit includes a control circuit CC and a switching array SWA. The control circuit CC includes a comparator, a control logic part, etc. The switching array SWA includes multiple switching elements SW. For example, at least a portion of the circuit elements included in the control circuit CC and the switching elements SW may be located on the semiconductor layer 22 or may be located on a circuit board other than the semiconductor layer 22.

As shown in FIG. 12, one switching element SW may be provided for one element region 10 (light-receiving element), or one switching element SW may be provided for multiple element regions 10. For example, one switching element SW is located between one first semiconductor region 11 and the first interconnect 51. Or, the switching element SW may be included in the first interconnect 51. For example, the switching element SW may be located between the first interconnect 51 and the pad 55.

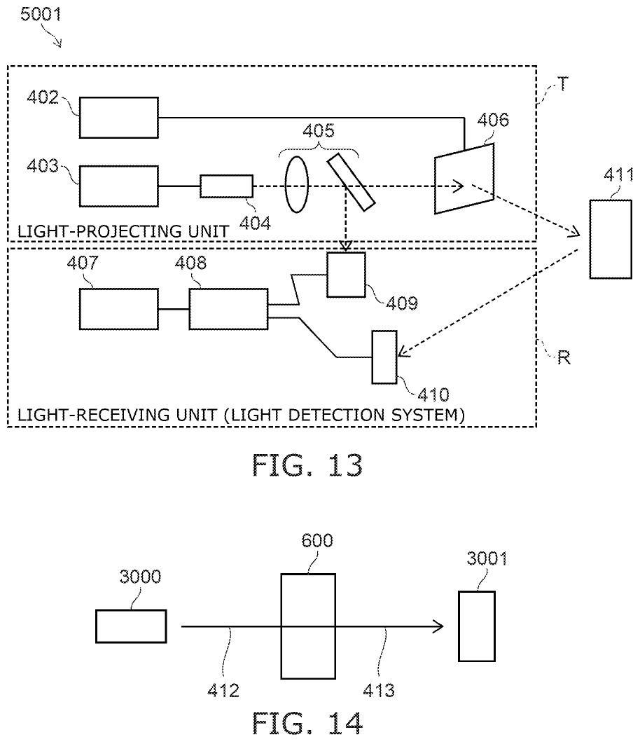

FIG. 13 is a schematic view illustrating a lidar (Laser Imaging Detection and Ranging (LIDAR)) device according to the embodiment.

The embodiment is applicable to a long-distance subject detection system (LIDAR) or the like that includes a line light source and a lens. The lidar device 5001 includes a light-projecting unit T projecting laser light toward an object 411, and a light-receiving unit R (also called a light detection system) receiving the laser light from the object 411, measuring the time of the round trip of the laser light to and from the object 411, and converting the time into a distance.

In the light-projecting unit T, a light source 404 emits light. For example, the light source 404 includes a laser light oscillator and produces laser light. A drive circuit 403 drives the laser light oscillator. An optical system 405 extracts a portion of the laser light as reference light, and irradiates the rest of the laser light on the object 411 via a mirror 406. A mirror controller 402 projects the laser light onto the object 411 by controlling the mirror 406. Herein, “project” means to cause the light to strike.

In the light-receiving unit R, a reference light detector 409 detects the reference light extracted by the optical system 405. A light detector 410 receives the reflected light from the object 411. A distance measuring circuit 408 measures the distance to the object 411 based on the reference light detected by the reference light detector 409 and the reflected light detected by the light detector 410. An image recognition system 407 recognizes the object 411 based on the measurement results of the distance measuring circuit 408.

The lidar device 5001 employs light time-of-flight ranging (Time of Flight) in which the time of the round trip of the laser light to and from the object 411 is measured and converted into a distance. The lidar device 5001 is applied to an automotive drive-assist system, remote sensing, etc. Good sensitivity is obtained particularly in the near-infrared region when the light detectors of the embodiments described above are used as the light detector 410. Therefore, the lidar device 5001 is applicable to a light source of a wavelength band that is invisible to humans. For example, the lidar device 5001 can be used for obstacle detection for a mobile body.

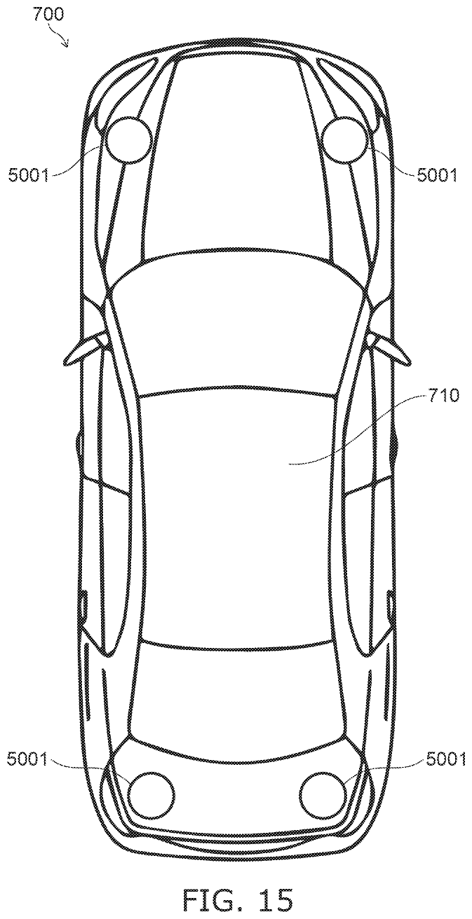

FIG. 14 describes the detection of the detection object of the lidar device.

A light source 3000 emits light 412 toward an object 600 that is the detection object. A light detector 3001 detects light 413 that passes through the object 600, is reflected by the object 600, or is diffused by the object 600.

For example, the light detector 3001 can realize highly-sensitive detection when the light detector according to the embodiment described above is used. It is favorable to provide multiple sets of the light detector 410 and the light source 404 and to preset the arrangement relationship in the software (which is replaceable with a circuit). For example, it is favorable for the arrangement relationship of the sets of the light detector 410 and the light source 404 to have uniform spacing. Thereby, an accurate three-dimensional image can be generated by the output signals of each light detector 410 complementing each other.

FIG. 15 is a schematic top view of a mobile body that includes the lidar device according to the embodiment.

In the example of FIG. 15, the mobile body is a vehicle. The vehicle 700 according to the embodiment includes the lidar devices 5001 at four corners of a vehicle body 710. Because the vehicle according to the embodiment includes the lidar devices at the four corners of the vehicle body, the environment in all directions of the vehicle can be detected by the lidar devices.

Other than the vehicle illustrated in FIG. 15, the mobile body may be a drone, a robot, etc. The robot is, for example, an automated guided vehicle (AGV). By including the lidar devices at the four corners of such mobile bodies, the environment in all directions of the mobile body can be detected by the lidar devices.

According to the embodiments described above, the detection efficiency of the light detector can be increased.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in light detectors such as Element regions, light concentrators, light-shielding parts, structure parts, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all light detectors, light detection systems, lidar devices, and mobile bodies practicable by an appropriate design modification by one skilled in the art based on the light detectors, the light detection systems, the lidar devices, and the mobile bodies described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light detector, comprising:
an element region including
a first semiconductor region of a first conductivity type, and
a second semiconductor region of a second conductivity type;
a light concentrator separated from the element region in a first direction, the light concentrator being configured to concentrate light incident on the light concentrator;
a structure part arranged with the element region in a direction crossing the first direction, the structure part having a different refractive index from the element region; and
a light-shielding part located between the element region and the light concentrator, the light-shielding part including an opening,
at least a portion of the light incident on the light concentrator being able to be incident on the element region by passing through the opening.

2. The detector according to claim 1, wherein
the light concentrator is configured to concentrate at least a portion of the light incident on the light concentrator toward the opening, and
the opening is arranged in the first direction with at least one of a center of the light concentrator or a center of the element region.

3. The detector according to claim 1, wherein
the light-shielding part includes an inner perimeter surface defining the opening, and
the inner perimeter surface is ring-shaped when viewed along the first direction.

4. The detector according to claim 1, further comprising:
a first insulating part located between the light concentrator and the light-shielding part,
the light concentrator being a lens that is convex in the first direction, a thickness along the first direction of the first insulating part being not less than f−λ/NA² and not more than f+λ/NA², where f is a focal length of the lens, λ is a wavelength of the light, and NA is a numerical opening of the lens.

5. The detector according to claim 1, further comprising:
an outer perimeter region surrounding the element region and including a semiconductor,
the structure part being positioned between the outer perimeter region and the element region.

6. The detector according to claim 5, wherein
the light-shielding part includes a portion arranged with the outer perimeter region in the first direction.

7. The detector according to claim 5, wherein
the light-shielding part is not arranged with the outer perimeter region in the first direction.

8. The detector according to claim 1, wherein
the light-shielding part includes an outer perimeter surface, and
the outer perimeter surface is ring-shaped when viewed along the first direction.

9. The detector according to claim 1, wherein
the light-shielding part includes an outer perimeter surface surrounding the opening, and
at least a portion of the outer perimeter surface is arranged with the element region in the first direction.

10. The detector according to claim 1, wherein
the light concentrator is a lens that is convex in the first direction, and
a diameter of the opening is not less than 1.22λ/NA, where λ is a wavelength of the light, and NA is a numerical opening of the lens.

11. The detector according to claim 1, wherein
a plurality of the openings is included,
a plurality of the light concentrators is included,
the plurality of openings is respectively positioned between one of the element regions and the plurality of light concentrators,
the plurality of light concentrators respectively concentrates at least a portion of the light incident on the plurality of light concentrators toward the plurality of openings, and
at least a portion of the light incident on the plurality of light concentrators is incident on the element region by passing respectively through the plurality of openings.

12. The detector according to claim 1, further comprising:
a first interconnect electrically connected with the first semiconductor region; and
a first electrode electrically connected with the first semiconductor region via the first interconnect,
the light-shielding part being conductive,
the light-shielding part being electrically connected with the first interconnect.

13. The detector according to claim 1, further comprising:
a first interconnect electrically connected with a first semiconductor region; and
a first electrode electrically connected with the first semiconductor region via the first interconnect,
the light-shielding part being electrically insulated from the first interconnect.

14. The detector according to claim 1, further comprising:
a resistor electrically connected with the element region, or a switching element electrically connected with the element region.

15. The detector according to claim 1, wherein
the element region is a p-i-n diode or an avalanche photodiode.

16. The detector according to claim 15, wherein
the avalanche photodiode operates in a Geiger mode.

17. A light detection system, comprising:
the detector according to claim 1; and
a distance measuring circuit calculating a time-of-flight of light based on an output signal of the detector.

18. A lidar device, comprising:
a light source irradiating light on an object; and
the light detection system according to claim 17,
the light detection system detecting light reflected by the object.

19. The device according to claim 18, further comprising:
an image recognition system generating a three-dimensional image based on an arrangement relationship of the light source and the detector.

20. A mobile body, comprising:
the device according to claim 18.
